(19) United States
(12) Patent Application Publication
(10) Pub. No.: US 2026/0096292 A1
(43) Pub. Date: Apr. 2, 2026

(54) DISPLAY DEVICE

(71) Applicant: LG Display Co., Ltd., Seoul (KR)

(72) Inventors: Byunggwan HYUN, Paju-si (KR); Uihyeon JEONG, Paju-si (KR); Jiyoon CHOI, Paju-si (KR)

(73) Assignee: LG Display Co., Ltd., Seoul (KR)

(21) Appl. No.: 19/285,437

(22) Filed: Jul. 30, 2025

(30) Foreign Application Priority Data
Oct. 2, 2024 (KR) 10-2024-0133594

(51) Int. Cl. H10K 59/122; H10K 59/123; H10K 59/40; H10K 59/80; H10K 102/00

(52) U.S. Cl. CPC H10K 59/122; H10K 59/123; H10K 59/40; H10K 59/8792; H10K 2102/311; H10K 2102/351

(57) ABSTRACT

A display device can include a substrate having a display area with a plurality of sub-pixels and a non-display area around the display area, a first transistor on the substrate, a second transistor on the first transistor, a first protective layer on the second transistor, a connection electrode connected to the second transistor on the first protective layer, a second protective layer on the connection electrode, a first electrode disposed in each of the sub-pixels on the second protective layer and connected to the connection electrode, and a bank disposed on the first electrode. The bank can be located at a boundary between adjacent sub-pixels and overlaps a periphery of an upper surface of the first electrode. Further, the bank can include a trench portion recessed in a thickness direction, in which the bank includes a black-based material.

### CROSS-REFERENCE TO RELATED APPLICATION

The present application claims priority to Korean Patent Application No. 10-2024-0133594, filed in the Republic of Korea on Oct. 2, 2024, the entire contents of which is hereby expressly incorporated by reference into the present application.

### BACKGROUND

### Technical Field

The present specification relates to a display device.

### Discussion of the Related Art

As the information society develops, various demands for display devices for displaying images are increasing, and various types of display devices such as liquid crystal display (LCD) devices and organic light emitting diode (OLED) display devices are utilized.

A display device includes a plurality of pixels and a plurality of switching elements for driving and controlling the pixels.

### SUMMARY OF THE DISCLOSURE

Embodiments of the present disclosure are directed to providing a display device which can have improved flexibility by omitting a polarizing unit and can be applied to a foldable product in which a display area is folded.

Embodiments of the present disclosure are also directed to providing a display device in which it is possible to improve external light introduced into a semiconductor layer.

Embodiments of the present disclosure are also directed to providing a display device in which it is possible to compensate for a low optical density in a trench.

Embodiments of the present disclosure are also directed to providing a display device with improved recycling.

Objects of the present disclosure are not limited to the above-described objects, and other technical objects can be inferred from the following embodiments.

According to one or more embodiments of the present disclosure, there is provided a display device including a substrate including a display area including a plurality of pixels, and a non-display area around the display area, a first transistor on the substrate, a second transistor on the first transistor, a first protective layer on the second transistor, a connection electrode connected to the second transistor on the first protective layer, a second protective layer on the connection electrode, a first electrode disposed in each of the sub-pixels on the second protective layer and connected to the connection electrode, and a bank disposed on the first electrode, located at a boundary between adjacent sub-pixels, overlapping a periphery of an upper surface of the first electrode, and including a trench recessed in a thickness direction, wherein the bank includes a black-based material, and the first protective layer or the second protective layer includes the black-based material.

According to another embodiment of the present disclosure, there is provided a display device including a substrate including a display area including a plurality of pixels, and a non-display area around the display area, a transistor on the substrate, a first protective layer on the transistor, a connection electrode connected to the transistor on the first protective layer, a second protective layer on the connection electrode, a first electrode disposed in each of the sub-pixels on the second protective layer and connected to the connection electrode, and a bank disposed on the first electrode, located at a boundary between adjacent sub-pixels, overlapping a periphery of an upper surface of the first electrode, and including a trench recessed in a thickness direction, wherein each of the first protective layer and the second protective layer has a greater thickness than the bank, the bank includes a black-based material, and the first protective layer or the second protective layer includes the black-based material.

Detailed matters of other embodiments of the present disclosure are included in the detailed description and accompanying drawings.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display device according to one or more embodiments of the present disclosure.

FIG. 2 is a cross-sectional view illustrating a bent state of a display panel according to FIG. 1.

FIG. 3 is a cross-sectional view along line A-A′ in FIG. 1.

FIG. 4 is a specific cross-sectional view of a light-emitting part of FIG. 3.

FIG. 5 is a specific cross-sectional view of a light-emitting part according to a modified example.

FIG. 6 is a cross-sectional view of a touch part according to FIG. 3.

FIG. 7 is a cross-sectional view along line B-B′ in FIG. 1.

FIG. 8 is a cross-sectional view along line C-C′ in FIG. 1.

FIG. 9 is an enlarged cross-sectional view of area Q1 in FIG. 3.

FIG. 10 is a cross-sectional view of a display device according to another embodiment of the present disclosure.

FIG. 11 is a cross-sectional view of a display device according to still another embodiment of the present disclosure.

FIG. 12 is a cross-sectional view of a display device according to yet another embodiment of the present disclosure.

FIG. 13 is a cross-sectional view of the display device according to yet another embodiment of the present disclosure.

FIG. 14 is a cross-sectional view of the display device according to yet another embodiment of the present disclosure.

FIG. 15 is a cross-sectional view of a display device according to yet another embodiment of the present disclosure.

FIG. 16 is a perspective view of a display device according to yet another embodiment of the present disclosure.

FIG. 17 is a cross-sectional view along line D-D′ in FIG. 16.

### DETAILED DESCRIPTION OF THE EMBODIMENTS

Hereinafter, embodiments of the present disclosure will be described with reference to the accompanying drawings.

The same reference numerals indicate the same components. In addition, in the drawings, thicknesses, proportions, and dimensions of components can be exaggerated for effective description of technical contents. Scales of components shown in the drawings differ from the actual scale for convenience of description, and thus are not limited to the scales shown in the drawings.

In the specification, when a first component (or an area, a layer, a portion, etc.) is described as “on,” “connected,” or “coupled to” a second component, it means that the first component can be directly connected/coupled to the second component or a third component can be disposed therebetween.

The term “and/or” includes all one or more combinations that can be defined by the associated configurations.

Terms such as first and second can be used to describe various components, but the components are not limited by the terms. The terms are used only for the purpose of distinguishing one component from another. For example, a first component can be referred to as a second component, and similarly, the second component can also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions can be positioned between two portions. The spatially relative terms “below or beneath,” “lower,” “above,” “upper,” etc. can be used to easily describe the correlation with one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element can be disposed “above” another element. Accordingly, the example term “below”can include both downward and upward directions.

It should be understood that term such as “includes” or “has” is intended to specify the presence of features, numbers, steps, operations, components, parts, or a combination thereof described in the disclosure and does not preclude the presence or addition possibility of one or more other features, numbers, steps, operations, components, parts, or combinations thereof in advance. Further, the term “can” fully encompasses all the meanings and coverages of the term “may” and vice versa.

Features of various embodiments of the present disclosure can be coupled or combined partially or entirely, various technological interworking and driving are made possible, and the embodiments can be implemented independently of each other or implemented together in an associated relationship.

Hereinafter, a display device of the present disclosure will be described with reference to the accompanying drawings and embodiments as follows. All the components of each display device according to all embodiments of the present disclosure are operatively coupled and configured.

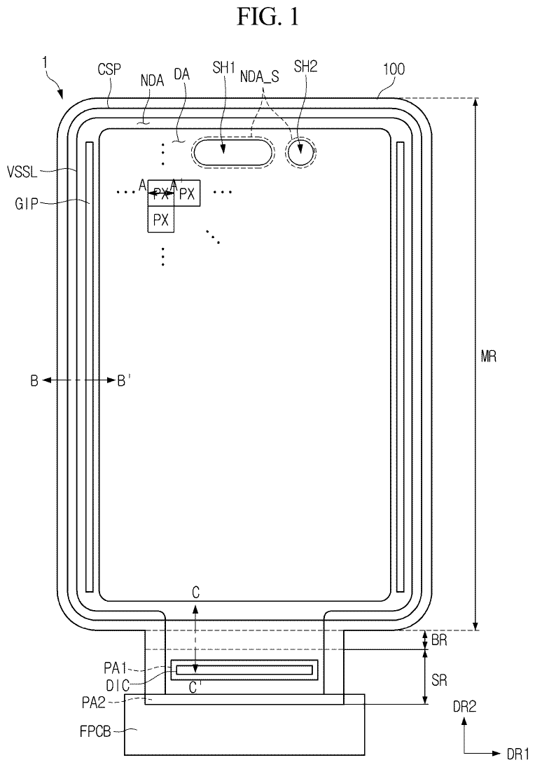

FIG. 1 is a plan view of a display device according to one or more embodiments of the present disclosure.

Referring to FIG. 1, a display device 1 according to one or more embodiments of the present disclosure can include a display panel 100. The display panel 100 can include a display area DA including a plurality of pixels PX and a non-display area NDA around the display area DA. The flat surface shape of the display area DA can have a rectangular shape. However, the embodiments of the present disclosure are not limited thereto, and the flat surface shape of the display area DA can be a square, circular, elliptical, or other polygonal shapes. For example, the display area DA can have a rectangular shape with rounded corners, but is not limited thereto and can also have a rectangular shape with angled corners.

In embodiments of the present disclosure, a first direction DR1 and a second direction DR2 are different directions and intersect each other, for example, directions that intersect vertically in a plan view. In FIG. 1, the first direction DR1 can be generally the same as an extension direction of short sides of the display panel 100, and the second direction DR2 can be the same as an extension direction of long sides of the display panel 100. However, the directions described in the embodiment should be understood as indicating relative directions, and the embodiment is not limited to the described direction.

The display area DA can include short sides extending in the first direction DR1 and long sides extending in the second direction DR2. The non-display area NDA can surround the display area DA. The non-display area NDA can be disposed at one side and the other side of the display area DA in the first direction DR1 and one side and the other side of the display area DA in the second direction DR2.

The display panel 100 can further include a sensor non-display area NDA_S and a sensor hole SH surrounded by the sensor non-display area NDA_S. The sensor hole SH1 and SH2 can be surrounded by the display area DA in a plan view. The sensor hole SH1 and SH2 can be, for example, two sensor holes as in FIG. 1, but the embodiments of the present disclosure are not limited thereto. For example, the sensor hole can be provided as one sensor hole. The two sensor holes SH1 and SH2 can each include a sensor hole in which an infrared sensor is disposed and a sensor hole in which a camera sensor is disposed, but the embodiments of the present disclosure are not limited thereto. The sensor non-display area NDA_S can be disposed between the sensor holes SH1 and SH2 and the display area DA. The sensor non-display area NDA_S can completely surround the sensor holes SH1 and SH2. A pixel PX may not be disposed in the sensor non-display area NDA_S.

A gate driving unit GIP can be disposed in the non-display area NDA located at one side and the other side of the display area DA in the first direction DR1. A low-potential voltage line VSSL can be disposed outside the gate driving unit GIP on the non-display area NDA. For example, as illustrated in FIG. 1, the low-potential voltage line VSSL can extend from a printed circuit board FPCB, pass a sub-region SR and a bending region BR, can be located outside the gate driving unit GIP on the non-display area NDA, and disposed to surround the display area DA.

The non-display area NDA located at the other side of the display area DA in the second direction DR2 can extend further from a central portion of the other side toward the other side of the display area DA in the second direction DR2. A width of the non-display area NDA in the first direction DR1 further extending from the central portion of the other side toward the other side of the display area DA in the second direction DR2 can be smaller than a width of the non-display area NDA in the first direction DR1 adjacent to the other side of the display area DA in the second direction DR2.

A display device 1 can include a main region MR, the sub-region SR, and the bending region BR between the main region MR and the sub-region SR. The display area DA and the non-display area NDA surrounding four surfaces of the display area DA can form the main region MR, and a portion extending from the central portion of the other side toward the other side of the display area DA in the second direction DR2 can form the bending region BR and the sub-region SR. The bending region BR can be disposed between the sub-region SR and the main region MR. The sub-region SR can include a first pad area PA1 and a second pad area PA2 located at an end portion of the other side of the sub-region SR in the second direction DR2. The display device 1 can further include a data driving unit DIC and a printed circuit board FPCB. The data driving unit DIC can be disposed in the first pad area PA1, and the printed circuit board FPCB can be attached to the second pad area PA2. A plurality of pads connected to the data driving unit DIC and the printed circuit board FPCB can be disposed in each of the first pad area PA1 and the second pad area PA2. A plurality of pads connected to the data driving unit DIC and the printed circuit board FPCB can be disposed in each of the first pad area PA1 and the second pad area PA2. The data driving unit DIC can be configured, for example, in the form of a driving chip (IC), but is not limited thereto. In one embodiment of the present disclosure, a case in which the data driving unit DIC is disposed by a chip on plastic method in which the data driving unit DIC is directly mounted on the display panel 100 is described, but the embodiments of the present disclosure are not limited thereto, and the data driving unit DIC can be disposed by a chip on glass or chip on film method.

The display panel 100 according to one embodiment of the present disclosure can further include a crack sensing pattern CSP surrounding the low-potential voltage line VSSL. The crack sensing pattern CSP can be disposed to completely surround the display area DA as illustrated in FIG. 1. For example, the crack sensing pattern CSP can be disposed outside the low-potential voltage line VSSL. However, the embodiments of the present disclosure are not limited thereto, and a part of the crack sensing pattern CSP may not be disposed in the non-display area NDA of the other side of the display area DA in the second direction DR2.

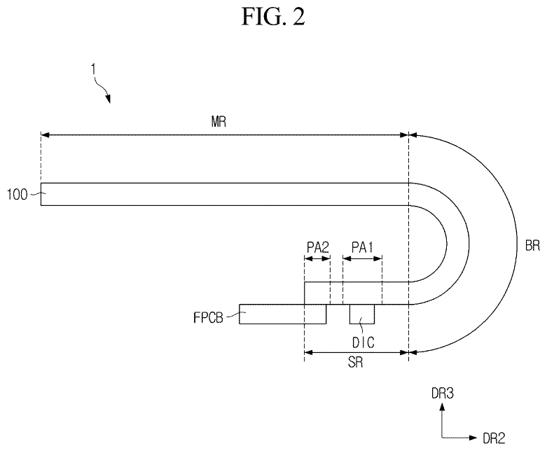

FIG. 2 is a cross-sectional view illustrating a bent state of a display panel according to FIG. 1.

Referring to FIG. 2, the bending region BR of the display panel 100 of the display device 1 according to one embodiment of the present disclosure can be bent in a thickness direction (or a third direction DR3). Accordingly, the main region MR and the sub-region SR can overlap each other in the thickness direction. The display panel 100 can be bent in such a manner that a lower surface of the main region MR faces an upper surface of the sub-region SR. The printed circuit board FPCB can be attached to an end portion of the sub-region SR.

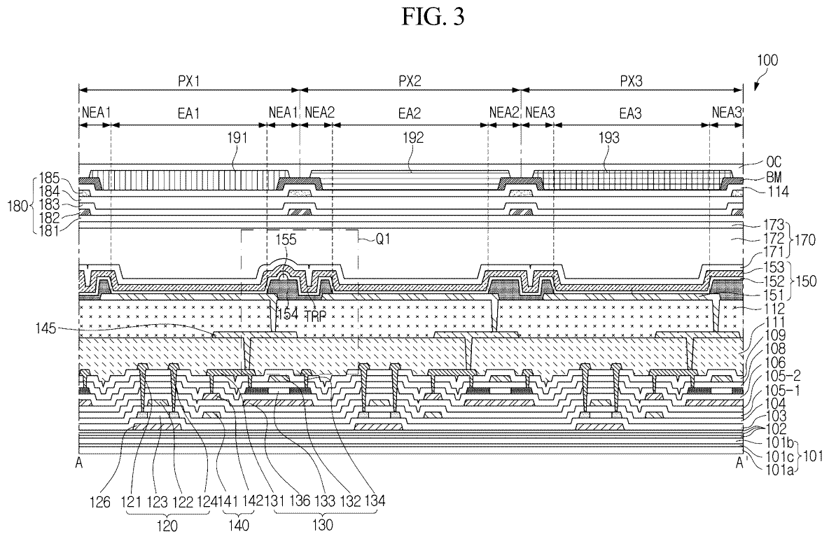

FIG. 3 is a cross-sectional view along line A-A′ in FIG. 1.

Referring to FIG. 3, the pixel PX (see FIG. 1) of the display panel 100 can include a plurality of sub-pixels PX1, PX2, and PX3. The first sub-pixel PX1 can be a red sub-pixel, the second sub-pixel PX2 can be a green sub-pixel, and the third sub pixel PX3 can be a blue sub-pixel, but the embodiments of the present disclosure are not limited thereto. In some embodiments of the present disclosure, the pixel PX further includes a fourth sub-pixel, and the fourth sub-pixel can be a white sub-pixel, but the embodiments of the present disclosure are not limited thereto. In some embodiments of the present disclosure, the pixel can include one red sub-pixel, two green sub-pixels, and one blue sub-pixel, but the embodiments of the present disclosure are not limited thereto. For example, the plurality of sub-pixels PX1, PX2, and PX3 can be arranged in a stripe manner in the first direction DR1, but are not limited thereto, and can be arranged in a pentile manner.

The display panel 100 can include a substrate 101, a first thin film transistor 120, a second thin film transistor 130, a light-emitting part 150, an encapsulation part 170, a touch part 180, a filter insulating layer 114, a black matrix BM, color filters 191, 192, and 193, and a planarization layer OC. The display panel 100 can include at least one panel insulating layer and at least one touch insulating layer between the substrate 101 and the light-emitting part 150. The at least one panel insulating layer can include at least one of a buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, and the at least one touch insulating layer can include at least one of a touch buffer layer 181, a first touch insulating layer 183, and a second touch insulating layer 184.

The substrate 101 can include one or more plastic materials. For example, the substrate 101 can be a multi-substrate including a plurality of plastic materials, such as polyimide, etc. For example, the substrate 101 can include a first substrate portion 101a and a second substrate portion 101b each including a plastic material, and a third substrate portion 101c including an inorganic insulation material between the first substrate portion 101a and the second substrate portion 101b, but the embodiments of the present disclosure are not limited thereto.

The buffer layer 102 can be disposed on the substrate 101. The buffer layer 102 can minimize or delay the diffusion of moisture or oxygen penetrating the substrate 101. The buffer layer 102 can be formed by alternately stacking silicon nitride (SiNₓ) and silicon oxide (SiOₓ) at least once, but the embodiments of the present disclosure are not limited thereto.

A first light-shielding layer 126 can be disposed on the buffer layer 102. The first light-shielding layer 126 can prevent light from transmitting a first semiconductor layer 123 of the first thin film transistor 120. For example, the first semiconductor layer 123 can be disposed to overlap the first light-shielding layer 126. The first light-shielding layer 126 can be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto.

The first insulating layer 103 can be disposed on the buffer layer 102 and the first light-shielding layer 126. The first insulating layer 103 can prevent a short circuit between a component of the first thin film transistor 120 and the first light-shielding layer 126. The first insulating layer 103 can be formed of the same material as the buffer layer 102, but the embodiments of the present disclosure are not limited thereto. For example, the first insulating layer 103 can be formed of an inorganic insulation material, such as silicon nitride (SiNₓ) or silicon oxide (SiOₓ), but the embodiments of the present disclosure are not limited thereto.

The first thin film transistor 120 can be disposed on the first insulating layer 103. The first thin film transistor 120 can include a first source electrode 121, a first gate electrode 122, the first semiconductor layer 123, and a first drain electrode 124.

The first semiconductor layer 123 can be disposed on the first insulating layer 103. The first semiconductor layer 123 can include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto. The first semiconductor layer 123 can include a channel area, a source area, and a drain area.

A second insulating layer 104 can be disposed on the first semiconductor layer 123. The second insulating layer 104 can be formed of the same material as the first insulating layer 103 and can prevent a short circuit between the first semiconductor layer 123 and another component of the first thin film transistor 120.

The first gate electrode 122 can be disposed on the second insulating layer 104. The first gate electrode 122 can be disposed on the second insulating layer 104 to overlap the channel area of the first semiconductor layer 123. The first gate electrode 122 can be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto. The first gate electrode 122 can be disposed along with a gate line.

The third insulating layers 105-1 and 105-2 can be disposed on the first gate electrode 122. The third insulating layers 105-1 and 105-2 can be formed by alternately stacking silicon nitride (SiNₓ) and silicon oxide (SiOₓ) at least once, but the embodiments of the present disclosure are not limited thereto. For example, the 3-1 insulating layer 105-1 can include silicon oxide (SiOₓ), and the 3-2 insulating layer 105-2 can include silicon nitride (SiNₓ), but the embodiments of the present disclosure are not limited thereto.

The first source electrode 121 and the first drain electrode 124 can be disposed on the third insulating layers 105-1 and 105-2.

The first source electrode 121 and the first drain electrode 124 can be electrically connected to the first semiconductor layer 123 through contact holes. The first source electrode 121 and the first drain electrode 124 can be formed of a metallic material. For example, the first source electrode 121 and the first drain electrode 124 can be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The first source electrode 121 and the first drain electrode 124 can be disposed along with a data line. For example, the data line can be formed of the same material as the first source electrode 121 and the first drain electrode 124 and formed on the same layer as the first source electrode 121 and the first drain electrode 124, but the embodiments of the present disclosure are not limited thereto.

A storage electrode 140 can be disposed to be spaced apart from the first thin film transistor 120. The storage electrode 140 can include a first storage electrode 141 and a second storage electrode 142.

The first storage electrode 141 can be formed of the same material as the first gate electrode 122 and disposed on the same layer as the first gate electrode 122, but the embodiments of the present disclosure are not limited thereto.

The second storage electrode 142 can be disposed on the first storage electrode 141. The second storage electrode 142 can be disposed on the third insulating layers 105-1 and 105-2, and the third insulating layers 105-1 and 105-2 between the first storage electrode 141 and the second storage electrode 142 can be used as a dielectric to generate a capacitance. The second storage electrode 142 can be formed of the same material as the first storage electrode 141, but the embodiments of the present disclosure are not limited thereto.

The second thin film transistor 130 can be disposed to be spaced apart from the first thin film transistor 120 and the storage electrode 140. The second thin film transistor 130 can include a second source electrode 131, a second gate electrode 132, a second semiconductor layer 133, and a second drain electrode 134.

A second light-shielding layer 136 can be disposed on the same layer as the second storage electrode 142.

The second light-shielding layer 136 can prevent light from traveling to the second semiconductor layer 133 similar to the first light-shielding layer 126, thereby extending the life of the second thin film transistor 130. For example, the second semiconductor layer 133 can be disposed to overlap the second light-shielding layer 136.

The fourth insulating layer 106 can be disposed on the second light-shielding layer 136. The fourth insulating layer 106 can be formed of the same material as the first insulating layer 103, the second insulating layer 104, or the third insulating layers 105-1 and 105-2, but the embodiments of the present disclosure are not limited thereto.

The second semiconductor layer 133 can be disposed on the fourth insulating layer 106. The second semiconductor layer 133 can include a source area, a drain area, and a channel area between the source area and the drain area.

The second semiconductor layer 133 can include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto.

The fifth insulating layer 108 can be disposed on the second semiconductor layer 133. The fifth insulating layer 108 can be formed of the same material as the first insulating layer 103, the second insulating layer 104, the third insulating layers 105-1 and 105-2, or the fourth insulating layer 106, but the embodiments of the present disclosure are not limited thereto.

The second gate electrode 132 can be disposed on the fifth insulating layer 108.

The second gate electrode 132 can be formed of the same material as the first gate electrode 122. For example, the second gate electrode 132 can be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto.

The sixth insulating layer 109 can be disposed on the second gate electrode 132. The sixth insulating layer 109 can be formed of the same material as the first insulating layer 103, the second insulating layer 104, the third insulating layers 105-1 and 105-2, the fourth insulating layer 106, or the fifth insulating layer 108, but the embodiments of the present disclosure are not limited thereto.

The first source electrode 121, the first drain electrode 124, the second source electrode 131, and the second drain electrode 134 can be disposed on the sixth insulating layer 109.

The second source electrode 131 and the second drain electrode 134 can be formed of the same material as the first source electrode 121 and the first drain electrode 124 and disposed on the same layer as the first source electrode 121 and the first drain electrode 124, but the embodiments of the present disclosure are not limited thereto. For example, the second source electrode 131 and the second drain electrode 134 can be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto. For example, the second source electrode 131 can be electrically connected to the second storage electrode 142. The second source electrode 131 can pass through the sixth insulating layer 109, the fifth insulating layer 108, and the fourth insulating layer 106 and can be electrically connected to the second storage electrode 142.

The first thin film transistor 120 can be a driving transistor, and the second thin film transistor 130 can be a switching transistor, but the embodiments of the present disclosure are not limited thereto.

A first protective layer 111 can be disposed on the first source electrode 121 and the first drain electrode 124.

The first protective layer 111 can planarize an upper portion of the first thin film transistor 120 and protect the first thin film transistor 120. The first protective layer 111 can be formed of an organic material. For example, the first conductive layer 111 can include a black-based material. For example, the first protective layer 111 can be formed of a material containing black pigment, or an organic material, such as a benzocyclobutene resin, a polyimide resin, an acrylic resin, a photosensitive polymer, etc., but the embodiments of the present disclosure are not limited thereto. For example, the first protective layer 111 can be formed of an organic material including an acrylic resin, an epoxy resin, a phenolic resin, a polyamide resin, or a polyimide resin, but the embodiments of the present disclosure are not limited thereto.

The second protective layer 112 can be disposed on the first protective layer 111. The second protective layer 112 can be formed of an organic material. For example, the second protective layer 112 can include a black-based material. For example, the second protective layer 112 can be formed of a material containing black pigment, or an organic material, such as a benzocyclobutene resin, a polyimide resin, an acrylic resin, a photosensitive polymer, etc., but the embodiments of the present disclosure are not limited thereto.

In some embodiments of the present disclosure, a third protective layer can be further disposed on an upper surface of the second protective layer 112, but the embodiments of the present disclosure are not limited thereto.

A connection electrode 145 can be disposed between the first protective layer 111 and the second protective layer 112.

The connection electrode 145 can electrically connect the first thin film transistor 120 to the light-emitting part 150. The connection electrode 145 can be formed of the same material as the first source electrode 121 and the first drain electrode 124, but the embodiments of the present disclosure are not limited thereto.

The connection electrode 145 can be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The light-emitting part 150 can be disposed on the second protective layer 112. The light-emitting part 150 can include a first electrode 151, an organic layer 152, and a second electrode 153. The first electrode 151 can serve as an anode, and the second electrode 153 can serve as a cathode.

The first electrode 151 can be disposed on the second protective layer 112. The first electrode 151 can be electrically connected to the first thin film transistor 120 through a contact hole formed in the second protective layer 112. The first electrode 151 can be a reflective electrode that reflects light, but the embodiments of the present disclosure are not limited thereto. The first electrode 151 can include a metallic material with high reflectance, such as a stacking structure (Ti/Al/Ti) of aluminum (Al) and titanium (Ti), a stacking structure (ITO/Al/ITO) of aluminum (Al) and indium tin oxide (ITO), or an APC alloy and can be formed of a single layer or multiple layers, but the embodiments of the present disclosure are not limited thereto.

The organic layer 152 can be disposed on the first electrode 151. The organic layer 152 can include one or more light-emitting structures (or light-emitting elements or elements) stacked on the first electrode 151 in the order or reverse order of a hole transfer layer and an electron transfer layer. For example, the hole transfer layer can include a hole transporting layer, a hole injecting layer, an electron blocking layer, a p-type charge generation layer, etc., but the embodiments of the present disclosure are not limited thereto. For example, the electron transfer layer can include an electron transporting layer, an electron injecting layer, a hole blocking layer, an n-type charge generation layer, etc., but the embodiments of the present disclosure are not limited thereto. The organic layer 152 can be an organic light-emitting layer, an inorganic light-emitting layer, a quantum dot light-emitting layer, a micro light-emitting diode, a micro mini light-emitting diode, etc., but the embodiments of the present disclosure area not limited thereto. For example, the organic layer 152 of the display panel 100 according to one embodiment of the present disclosure can include an organic light-emitting layer. The organic layer 152 can include a red light-emitting layer, a green light-emitting layer, and a blue light-emitting layer. The organic layer 152 can be a white light-emitting layer, but the embodiments of the present disclosure are not limited thereto. Hereinafter, a specific structure of the organic layer 152 according to one embodiment will be described.

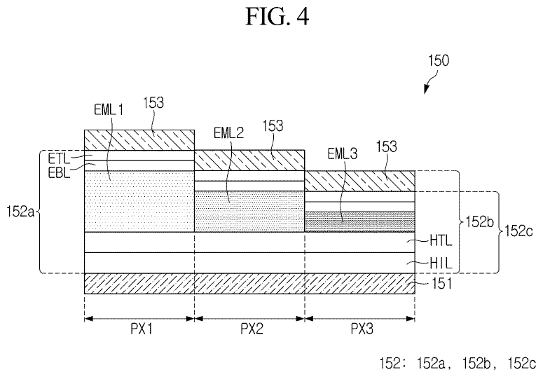

FIG. 4 is a specific cross-sectional view of a light-emitting part of FIG. 3.

Referring to FIG. 4, the light-emitting part 150 can include the first sub-pixel PX1, the second sub-pixel PX2, and the third sub-pixel PX3.

A thickness of the light-emitting part 150 in each sub-pixel PX1, PX2, or PX3 can be different, but the embodiments of the present disclosure are not limited thereto, and the thickness of the light-emitting part 150 in each sub-pixel PX1, PX2, or PX3 can be the same.

The organic layer 152 can include a first organic layer 152a disposed in the first sub-pixel PX1, a second organic layer 152b disposed in the second sub-pixel PX2, and a third organic layer 152c disposed in the third sub-pixel PX3. The light-emitting layers EML1, EML2, and EML3 of the organic layers 152a, 152b, and 152c can be physically separated, but lower layers and upper layers of the light-emitting layers EML1, EML2, and EML3 can be formed integrally across the sub-pixels PX1, PX2, and PX3. A thicknesses of each light-emitting layer EML1, EML2, or EML3 can be different. For example, a thickness of a first light-emitting layer EML1 can be the greatest, a thickness of a second light-emitting layer EML2 can be the second greatest, and a thickness of the third light-emitting layer EML3 can be the smallest, but the embodiments of the present disclosure are not limited thereto.

A hole injecting layer HIL can be disposed on the first electrode 151. The hole injecting layer HIL can be located between the first electrode 151 and the light-emitting layers EML1, EML2, and EML3. The hole injecting layer HIL can be formed integrally across the sub-pixels PX1, PX2, and PX3. For example, the hole injecting layer HIL can be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A hole transporting layer HTL can be disposed on the hole injecting layer HIL. The hole transporting layer HTL can be located between the hole injecting layer HIL and the light-emitting layers EML1, EML2, and EML3. The hole transporting layer HTL can be formed integrally across the sub-pixels PX1, PX2, and PX3. The hole transporting layer HTL can be formed of one or more selected from the group consisting of arylamine-based materials, such as NPB (N, N-naphthyl-N, N′-phenyl benzidine), TPD (N, N′-bis-(3-methylphenyl)-N, N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N, N-dinaphthylN, N′-diphenyl benzidine), s-TAD, and MTDATA(4,4′,4″-Tris(N-3-methylphenyl-N-phenyl-amino)-triphenylamine), but the embodiments of the present disclosure are not limited thereto.

The light-emitting layers EML1, EML2, and EML3 can be disposed on the hole transporting layer HTL. The first light-emitting layer EML1 can be disposed in the first sub-pixel PX1, the second light-emitting layer EML2 can be disposed in the second sub-pixel PX2, and the third light-emitting layer EML3 can be disposed in the third sub-pixel PX3.

A thicknesses of each light-emitting layer EML1, EML2, or EML3 can be different. For example, the first light-emitting layer EML1 can be formed in a thickness of 60 to 80 nm, the second light-emitting layer EML2 can be formed in a thickness of 30 to 50 nm, and the third light-emitting layer EML3 can be formed in a thickness of 10 to 30 nm, but the embodiments of the present disclosure are not limited thereto.

Each of the first light-emitting layer EML1, the second light-emitting layer EML2, and the third light-emitting layer EML3 can include a material that can emit light in the visible light range by receiving and combining holes and electrons.

An electron blocking layer EBL can be disposed on each light-emitting layer EML1, EML2, or EML3. The electron blocking layer EBL can be disposed integrally across the sub-pixels PX1, PX2, and PX3.

An electron transporting layer ETL can be disposed on the electron blocking layer EBL. The electron transporting layer ETL can be disposed integrally across the sub-pixels PX1, PX2, and PX3. The electron transporting layer ETL can be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The second electrode 153 can be disposed on the electron transporting layer ETL.

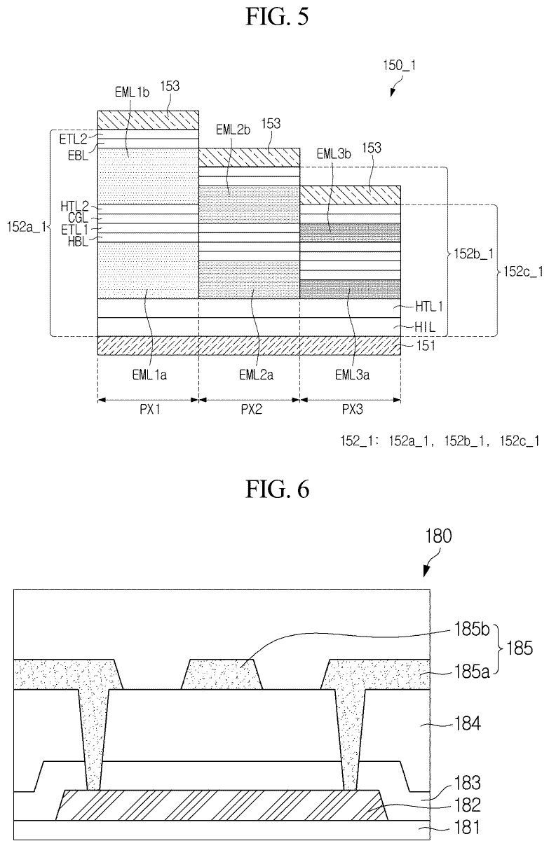

FIG. 5 is a specific cross-sectional view of a light-emitting part according to a modified example.

Referring to FIGS. 4 and 5, an organic layer 152_1 can include a first organic layer 152a_1 disposed in the first sub-pixel PX1, a second organic layer 152b_1 disposed in the second sub-pixel PX2, and a third organic layer 152c_1 disposed in the third sub-pixel PX3.

The light-emitting layers of each organic layer 152a_1, 152b_1, or 152c_1 can be physically separated, but the lower layers and upper layers of the light-emitting layers can be formed integrally across the sub-pixels PX1, PX2, and PX3. The thickness of each light-emitting layer can be different. For example, the thickness of the first light-emitting layer of the first sub-pixel can be the greatest, the thickness of the second light-emitting layer of the second sub-pixel can be the second greatest, and the thickness of the third light-emitting layer of the third sub-pixel can be the smallest, but the embodiments of the present disclosure are not limited thereto. In addition, the light-emitting layers of each organic layer 152a_1, 152b_1, or 152c_1 can be provided as two or more light-emitting layers.

A hole injecting layer HIL can be disposed on the first electrode 151. The hole injecting layer HIL can be located between the first electrode 151 and the light-emitting layers EML1a, EML2a, and EML3a. The hole injecting layer HIL can be formed integrally across the sub-pixels PX1, PX2, and PX3. For example, the hole injecting layer HIL can be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A first hole transporting layer HTL1 can be disposed on the hole injecting layer HIL. The first hole transporting layer HTL1 can be located between the hole injecting layer HIL and light-emitting layers EML1a, EML2a, and EML3a. The first hole transporting layer HTL1 can be formed integrally across the sub-pixels PX1, PX2, and PX3. The first hole transporting layer HTL1 can be formed of one or more selected from the group consisting of arylamine-based materials, such as NPB (N, N-naphthyl-N, N′-phenyl benzidine), TPD (N, N′-bis-(3-methylphenyl)-N, N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N, N-dinaphthylN, N′-diphenyl benzidine), s-TAD, and MTDATA(4,4′,4″-Tris(N-3-methylphenyl-N-phenyl-amino)-triphenylamine), but the embodiments of the present disclosure are not limited thereto.

The light-emitting layers EML1a, EML2a, and EML3a can be disposed on the first hole transporting layer HTL1. A 1-1 light-emitting layer EML1a can be disposed in the first sub-pixel PX1, a 2-1 light-emitting layer EML2a can be disposed in the second sub-pixel PX2, and a 3-1 light-emitting layer EML3a can be disposed in the third sub-pixel PX3. Each of the light-emitting layers EML1a, EML2a, and EML3a can be the same as each of the light-emitting layers EML1, EML2, and EML3 of FIG. 4.

A thicknesses of each light-emitting layer EML1a, EML2a, or EML3a can be different. For example, the 1-1 light-emitting layer EML1a can be formed in a thickness of 60 to 80 nm the 2-1 light-emitting layer EML2a can be formed in a thickness of 30 to 50 nm, and the 3- 1 light-emitting layer EML3a can be formed in a thickness of 10 to 30 nm, but the embodiments of the present disclosure are not limited thereto.

A hole blocking layer HBL can be disposed on each light-emitting layer EML1a, EML2a, or EML3a. The hole blocking layer HBL can be disposed integrally across the sub-pixels PX1, PX2, and PX3.

A first hole transporting layer ETL1 can be disposed on the hole blocking layer HBL. The first electron transporting layer ETL1 can be formed integrally across the sub-pixels PX1, PX2, and PX3. The first electron transporting layer ETL1 can be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

A common charge layer CGL can be disposed on the first electron transporting layer ETL1. The common charge layer CGL can be disposed between the first electron transporting layer ETL1 and the second hole transporting layer HTL2. The common charge layer CGL can include a conductive material, but the embodiments of the present disclosure are not limited thereto.

A second hole transporting layer HTL2 can be disposed on the common charge layer CGL. The second hole transporting layer HTL2 can be disposed between the hole blocking layer HBL and the light-emitting layers EML1b, EML2b, and EBL3b. The second hole transporting layer HTL2 can be formed integrally across the sub-pixels PX1, PX2, and PX3. A material of the second hole transporting layer HTL2 can be the same as a material of the first hole transporting layer HTL1, but the embodiments of the present disclosure are not limited thereto.

The light-emitting layers EML1b, EML2b, and EML3b can be disposed on the second hole transporting layer HTL2. A 1-2 light-emitting layer EML1b can be disposed in the first sub-pixel PX1, a 2-2 light-emitting layer EML2b can be disposed in the second sub-pixel PX2, and a 3-2 light-emitting layer EML3b can be disposed in the third sub-pixel PX3. Each of the light-emitting layers EML1b, EML2b, and EML3b can be the same as each of the light-emitting layers EML1a, EML2a, and EML3a.

A thicknesses of each light-emitting layer EML1b, EML2b, or EML3b can be different. For example, the 1-2 light-emitting layer EML1b can be formed in a thickness of 600 to 800, the 2-2 light-emitting layer EML2b can be formed in a thickness of 300 to 500, and the 3-2 light-emitting layer EML3b can be formed in a thickness of 100 to 300, but the embodiments of the present disclosure are not limited thereto.

An electron blocking layer EBL can be disposed on each light-emitting layer EML1b, EML2b, or EML3b. The electron blocking layer EBL can be disposed integrally across the sub-pixels PX1, PX2, and PX3.

An electron transporting layer ETL can be disposed on the electron blocking layer EBL. The electron transporting layer ETL can be disposed integrally across the sub-pixels PX1, PX2 and PX3. The electron transporting layer ETL can be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The second electrode 153 can be disposed on the electron transporting layer ETL.

Referring back to FIG. 3, the second electrode 153 can be disposed on the organic layer 152. The second electrode 153 can be a transparent electrode that transmits light, but the embodiments of the present disclosure are not limited thereto. For example, the second electrode 153 can include a transparent conductive material, such as indium tin oxide (ITO) or indium zinc oxide (IZO), or a metal that transmits visible light, but the embodiments of the present disclosure are not limited thereto.

The bank 154 can be disposed to expose the first electrode 151. The bank 154 can define openings (or the light-emitting areas EA1, EA2, and EA3) of the sub-pixels PX1, PX2, and PX3 and can be disposed to cover an edge portion (or a periphery) of the first electrode 151. For example, the first sub-pixel PX1 can include a first light-emitting area EA1 and a first non-light-emitting area NEA1 around the first light-emitting area EA1, the second sub-pixel PX2 can include a second light-emitting area EA2 and a second non-light-emitting area NEA2 around the second light-emitting area EA2, and the third sub-pixel PX3 can include a third light-emitting area EA3 and a third non-light-emitting area NEA3 around the third light-emitting area EA3. For example, each non-light-emitting area NEA1, NEA2, or NEA3 can correspond to a boundary between adjacent sub-pixels PX1, PX2, and PX3. The bank 154 can define the light-emitting areas EA1, EA2, and EA3.

The bank 154 can include a black-based material. For example, the bank 154 can be formed of a material containing black pigment, or an organic material, such as a benzocyclobutene resin, a polyimide resin, an acrylic resin, a photosensitive polymer, etc., but the embodiments of the present disclosure are not limited thereto. When the bank 154 is formed of a material containing black pigment or black dye, the bank 154 can be an opaque bank. When the bank 154 is formed of a material containing black pigment or black dye, it is possible to shield external light or light reflected from the outside, thereby further increasing the luminance of the display device.

In a trench TRP, the bank 154 can be recessed in the thickness direction. For example, a thickness of the bank 154 in the trench TRP can be smaller than a thickness of the bank 154 in which the trench TRP is not disposed. In some embodiments of the present disclosure, the trench is not formed in the bank 154, and a separate structure can be disposed on the bank. The structure can have a reversely-tapered shape and physically separate the organic layer 152 at the boundaries between the sub-pixels PX1, PX2, and PX3.

A spacer 155 can be further disposed on the bank 154. For example, the spacer 155 can be a transparent bank, but is not limited thereto, and the spacer 155 can be formed of the same material as the bank 154. For example, the spacer can be disposed on at least one of the boundaries between the first to third sub-pixels PX1, PX2, and PX3, but the embodiments of the present disclosure are not limited thereto. In some embodiments of the present disclosure, the bank 154 and the spacer 155 can be formed of the same material and formed simultaneously through a halftone mask or a slit mask, but the embodiments of the present disclosure are not limited thereto.

The organic layer 152 can be disposed on the first electrode 151 and the bank 154. The second electrode 153 can be disposed on the organic layer 152. The organic layer 152 and the second electrode 153 can be disposed across the sub-pixels PX1, PX2, and PX3. The organic layer 152 according to one embodiment can be disposed across the sub-pixels PX1, PX2, and PX3, and in the non-light-emitting areas NEA1, NEA2, and NEA3, a current path can be increased by the trench TRP. Accordingly, it is possible to minimize the lateral leakage current of the organic layer 152 to the adjacent sub-pixels PX1, PX2, and PX3.

The encapsulation part 170 can be disposed on the second electrode 153. The encapsulation part 170 can include one or more insulating layers. For example, the encapsulation part 170 can include a first encapsulation layer 171, a second encapsulation layer 172 disposed on the first encapsulation layer 171, and a third encapsulation layer 173 disposed on the second encapsulation layer 172. The encapsulation part 170 can include one or more inorganic insulation material layers and one or more organic material layers. For example, the first encapsulation layer 171 and the third encapsulation layer 173 can include an inorganic insulation material, and the second encapsulation layer 172 can include an organic material, but the embodiments of the present disclosure are not limited thereto.

The touch part 180 can be disposed on the encapsulation part 170. The touch part 180 can include the touch buffer layer 181, a first touch conductive layer, the first touch insulating layer 183, the second touch insulating layer 184, and a second touch conductive layer. In some embodiments of the present disclosure, one or more touch organic layers can be further disposed on the second touch conductive layer, but the embodiments of the present disclosure are not limited thereto.

FIG. 6 is a cross-sectional view of a touch part according to FIG. 3.

Referring to FIGS. 3 and 6, the touch buffer layer 181 can be disposed on the encapsulation part 170. For example, a touch buffer layer 181 can be disposed on the third encapsulation layer 173. The touch buffer layer 181 can be formed of the same material as the buffer layer 102, but the embodiments of the present disclosure are not limited thereto.

The first touch conductive layer can be disposed on the touch buffer layer 181. The first touch conductive layer can include a bridge electrode 182. The bridge electrode 182 and a sensor electrode 185 to be described below can be disposed at each of the boundaries between adjacent sub-pixels PX1, PX2, and PX3. For example, the bridge electrode 182 and the sensor electrode 185 can be disposed in the non-light-emitting areas NEA1, NEA2, and NEA3. The bridge electrode 182 and the sensor electrode 185 can overlap the black matrix BM to be described below in the thickness direction. The black matrix BM can cover the bridge electrode 182 and the sensor electrode 185. Accordingly, the bridge electrode 182 and the sensor electrode 185 can be prevented from being visible from the outside.

The first touch insulating layer 183 and the second touch insulating layer 184 disposed on the first touch insulating layer 183 can be disposed on the first touch conductive layer. The first touch insulating layer 183 and the second touch insulating layer 184 disposed on the first touch insulating layer 183 can prevent a short circuit between the first touch conductive layer and the second touch conductive layer. The first touch insulating layer 183 can be formed of silicon oxide (SiOₓ), silicon nitride (SiNₓ), or multiple layers thereof, but the embodiments of the present disclosure are not limited thereto. The second touch insulating layer 184 can include an organic insulation material, but the embodiments of the present disclosure are not limited thereto, and the second touch insulating layer 184 can include the same material as the first touch insulating layer 183.

The second touch conductive layer can be disposed on the second touch insulating layer 184. The second touch conductive layer can include a first sensor electrode 185a and a second sensor electrode 185b. The sensor electrode 185 can include the first sensor electrode 185a extending in the first direction DR1 (see FIG. 1) and the second sensor electrode 185b extending in the second direction DR2 (see FIG. 1) different from the first direction DR1.

The bridge electrode 182 can be electrically connected to the first sensor electrode 185a through a contact hole formed in the first touch insulating layer 183 and the second touch insulating layer 184. For example, the first sensor electrode 185a and the bridge electrode 182 can extend in the first direction DR1 (see FIG. 1).

The sensor electrode 185 and the bridge electrode 182 can include a metallic material. For example, the sensor electrode 185 and the bridge electrode 182 can be formed of titanium (Ti), nickel (Ni), aluminum (Al), or an alloy thereof and formed of a triple layer, such as titanium (Ti)/aluminum (Al)/titanium (Ti), but the embodiments of the present disclosure are not limited thereto.

A filter insulating layer 114 can be disposed on the second touch conductive layer. The filter insulating layer 114 can be formed of an inorganic insulation material, such as silicon nitride (SiNₓ) or silicon oxide (SiOₓ), but the embodiments of the present disclosure are not limited thereto.

The black matrix BM can be disposed on the filter insulating layer 114. The black matrix BM can include a black-based material. For example, the black matrix BM can include a light-blocking material or a light-absorbing material. For example, the black matrix BM can be formed of a material including a black pigment, a black dye, etc. The black matrix BM can cover the bridge electrode 182 and the sensor electrode 185. Accordingly, the bridge electrode 182 and the sensor electrode 185 can be prevented from being visible from the outside. For example, a width of the black matrix BM can be smaller than a width of the bank 154.

For example, spacing distances between an end of the black matrix BM and boundaries between the light-emitting areas EA1, EA2, and EA3 and the non-light-emitting areas NEA1, NEA2, and NEA3 can be longer than spacing distances between an end of the bank 154 and the boundaries between the light-emitting areas EA1, EA2, and EA3 and the non-light-emitting areas NEA1, NEA2, and NEA3. The end of the bank 154 can be aligned with the boundaries between the light-emitting areas EA1, EA2, and EA3 and the non-light-emitting areas NEA1, NEA2, and NEA3, but the embodiments of the present disclosure are not limited thereto. In the case of the display panel 100 according to one embodiment, since the bank 154 can include a black-based material and the spacing distances between an end of the black matrix BM and boundaries between the light-emitting areas EA1, EA2, and EA3 and the non-light-emitting areas NEA1, NEA2, and NEA3 can be longer than spacing distances between an end of the bank 154 and the boundaries between the light-emitting areas EA1, EA2, and EA3 and the non-light-emitting areas NEA1, NEA2, and NEA3, light emitted from the light-emitting areas EA1, EA2, and EA3 can be emitted upward with a greater viewing angle as much as a spacing space between the end of the black matrix BM and the boundaries between the light-emitting areas EA1, EA2, and EA3 and the non-light-emitting areas NEA1, NEA2, and NEA3. Accordingly, it is possible to minimize a reduction in luminance according to a viewing angle. However, when the spacing distances between an end of the black matrix BM and boundaries between the light-emitting areas EA1, EA2, and EA3 and the non-light-emitting areas NEA1, NEA2, and NEA3 can be longer than spacing distances between an end of the bank 154 and the boundaries between the light-emitting areas EA1, EA2, and EA3 and the non-light-emitting areas NEA1, NEA2, and NEA3 and the bank 154 is formed of only a transparent material, light incident from the outside can be reflected by the bank 154, resulting in visible ring-shaped spots. However, in the case of the display panel 100 according to one embodiment of the present disclosure, the light incident from the outside can be absorbed or blocked by the bank 154 including a black-based material, thereby preventing the occurrence of the ring-shaped spots.

The color filters 191, 192, and 193 can be disposed on the black matrix BM. The color filters 191, 192, and 193 can be disposed on the first to third sub-pixels PX1, PX2, and PX3, respectively, and can block specific colors from light emitted from the light-emitting area EA1, EA2, and EA3 of the sub-pixels PX1, PX2, and PX3. The first color filter 191 can be provided to block light of other colors not including red (R) light. In this case, the first color filter 191 can be provided as a red color filter. The second color filter 192 can be provided to block light of other colors not including green (G) light. In this case, the second color filter 192 can be provided as a green color filter. A third color filter 193 provided in the third sub-pixel PX3 can be provided to block light of other colors not including blue (B) light. In this case, the third color filter 193 can be provided as a blue color filter. However, the embodiments of the present disclosure are not limited thereto.

For example, each color filter 191, 192, or 193 can come into direct contact with side and upper surfaces of the black matrix BM. For example, each color filter 191, 192, or 193 can be spaced apart from the boundaries of adjacent sub-pixels PX1, PX2, and PX3, but the embodiments of the present disclosure are not limited thereto, and the color filters 191, 192, and 193 can overlap each other in the thickness direction.

The planarization layer OC can be disposed on the color filters 191, 192, and 193. The planarization layer OC can serve to planarize a step formed by the color filters 191, 192, and 193. For example, the planarization layer OC can include an organic insulation material.

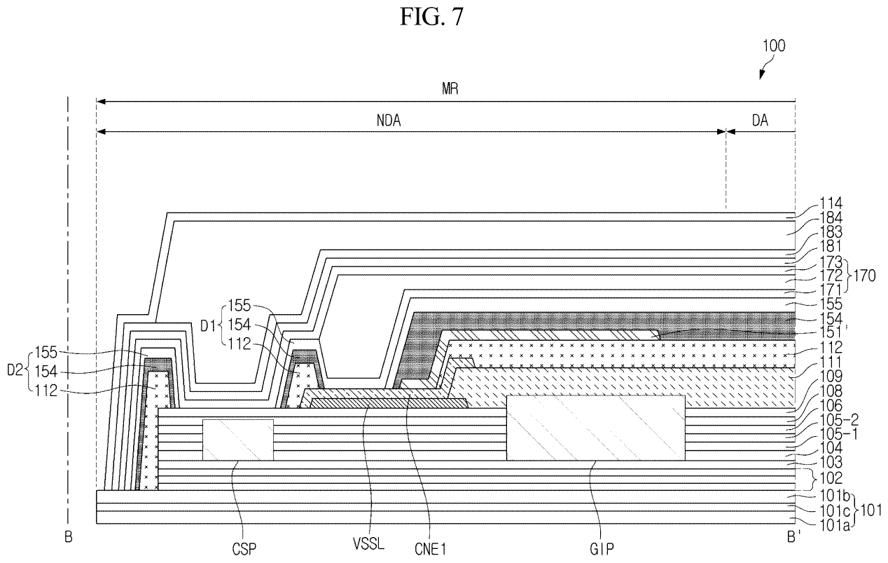

FIG. 7 is a cross-sectional view along line B-B′ in FIG. 1.

Referring to FIG. 7, at least one of the panel inorganic layers 102, 103, 104, 105-1, 105-2, 106, 108, and 109 may not extend to an end portion of the substrate 101. For example, the at least one of the panel inorganic layers 102, 103, 104, 105-1, 105-2, 106, 108, and 109 can expose the end portion of the substrate 101, but the embodiments of the present disclosure are not limited thereto.

The display panel 100 according to one embodiment can further include the crack sensing pattern CSP, the low-potential voltage line VSSL, and the gate driving unit GIP. As described above in FIG. 1, the low-potential voltage line VSSL can be located between the crack sensing pattern CSP and the display area DA, and the gate driving unit GIP can be located between the low-potential voltage line VSSL and the display area DA.

For example, as illustrated in FIG. 7, the gate driving unit GIP can be formed of a conductive layer located on the same layer as the first gate electrode 122 (see FIG. 3), a conductive layer located on the same layer as the second light-shielding layer 136 (see FIG. 3), or a conductive layer located on the same layer as the first source electrode 121, but the embodiments of the present disclosure are not limited thereto.

For example, the crack sensing pattern CSP can be disposed between a first dam D1 and a second dam D2. The crack sensing pattern CSP can be formed of a conductive layer located on the same layer as the first gate electrode 122 (see FIG. 3) or a conductive layer located on the same layer as the second light-shielding layer 136 (see FIG. 3), but the embodiments of the present disclosure are not limited thereto. For example, the crack sensing pattern CSP can include a conductive layer located on the same layer as the first source electrode 121, but the embodiments of the present disclosure are not limited thereto.

The low-potential voltage line VSSL can be disposed between the crack sensing pattern CSP and the gate driving unit GIP. The low-potential voltage line VSSL can be formed of a conductive layer located on the same layer as the first source electrode 121, but the embodiments of the present disclosure are not limited thereto.

The first protective layer 111 can cover the gate driving unit GIP, partially cover one end portion of the low-potential voltage line VSSL, and expose the other end portion of the low-potential voltage line VSSL. In the present disclosure, the one end portion can refer to an area of a certain component, which is located in a direction from the non-display area NDA toward the display area DA, and the other end portion can refer to an area of the certain component, which is located in a direction from the display area DA toward the non-display area NDA.

A first connection electrode CNE1 located on the same layer as the connection electrode 145 can be disposed on the first protective layer 111. The first connection electrode CNE1 can be directly connected to an area of the low-potential voltage line VSSL, in which the first protective layer 111 is exposed. The first connection electrode CNE1 can cover the other end portion of the low-potential voltage line VSSL, but the embodiments of the present disclosure are not limited thereto.

The second protective layer 112 can be disposed on the first connection electrode CNE1. The second protective layer 112 can come into direct contact with and cover one end portion of the first connection electrode CNE1 and expose the other end portion of the first connecting electrode CNE1. The second protective layer 112 can form a first layer of the first dam D1 and a first layer of the second dam D2. The second dam D2 can overlap, for example, the low-potential voltage line VSSL and cover the other end portion of the low-potential voltage line VSSL. The second dam D2 can come into direct contact with the first connection electrode CNE1 and cover the other end portion of the first connection electrode CNE1. The second protective layer 112 forming the first layer of the first dam D1 can come into direct contact with the exposed side surfaces of at least one of the panel inorganic layers 102, 103, 104, 105, 106, 107, and 109 and can come into direct contact with the upper surface of the substrate 101, but the embodiments of the present disclosure are not limited thereto. The second protective layer 112 can overlap the gate driving unit GIP. In the present disclosure, the dam is, for example, provided as two dams, but the dam can be provided as three or more dams or one dam.

A low-potential connection electrode 151′ located on the same layer as the first electrode 151 (see FIG. 3) can be disposed on the first connection electrode CNE1 exposed by the second protective layer 112 and the second protective layer 112. The low-potential connection electrode 151′ can be electrically connected to the first connection electrode CNE1 exposed by the second protective layer 112. The low-potential connection electrode 151′ can be electrically connected to the second electrode 153 (see FIG. 3) described above in FIG. 3.

The bank 154 can be disposed on the low-potential connection electrode 151′ and the second protective layer 112. The bank 154 can overlap the gate driving unit GIP and the low-potential connection electrode 151′ and cover the other end portion of the low-potential connection electrode 151′. The bank 154 can completely cover the low-potential connection electrode 151′, but the embodiments of the present disclosure are not limited thereto. The bank 154 can expose a central portion and the other end portion of the first connection electrode CNE1, but the embodiments of the present disclosure are not limited thereto. The bank 154 can form a second layer of the first dam D1 and a second layer of the second dam D2. In each dam D1 or D2, the bank 154 can overlap the second protective layer 112 forming the first layer and completely cover the second protective layer 112, but the embodiments of the present disclosure are not limited thereto. In the second dam D2, the bank 154 can come into contact with the side surfaces of the second protective layer 112 and the upper surface of the substrate 101, but the embodiments of the present disclosure are not limited thereto.

The spacer 155 can be disposed on the bank 154. The spacer 155 can overlap the gate driving unit GIP. The spacer 155 can form a third layer of the dams D1 and D2. The spacer 155 forming the third layer of each dam D1 or D2 can overlap the bank 154 forming the second layer and completely cover the bank 154, but the embodiments of the present disclosure are not limited thereto. In the second dam D2, the spacer 155 can come into contact with the side surfaces of the bank 154 and the upper surface of the substrate 101, but the embodiments of the present disclosure are not limited thereto.

The encapsulation part 170 can be disposed on the spacer 155. The first encapsulation layer 171 can extend to the gate driving unit GIP, the low-potential voltage line VSSL, the first dam D1, and the second dam D2 and cover an outer surface of the second dam D2. The second encapsulation layer 172 can end at the first dam D1. The second encapsulation layer 172 can overlap the gate driving unit GIP and the low-potential voltage line VSSL. The third encapsulation layer 173 can extend to the gate driving unit GIP, the low-potential voltage line VSSL, the first dam D1, and the second dam D2 and come into direct contact with the first encapsulation layer 171 on the first dam D1, the crack sensing pattern CSP, and the second dam D2.

The touch buffer layer 181 and the first touch insulating layer 183 can extend to the gate driving unit GIP, the low-potential voltage line VSSL, the first dam D1, and the second dam D2 and cover the outer surface of the second dam D2. The second touch insulating layer 184 can extend to the gate driving unit GIP, the low-potential voltage line VSSL, the first dam D1, and the crack sensing pattern CSP and end on the second dam D2, but the embodiments of the present disclosure are not limited thereto.

The filter insulating layer 184 can extend to the gate driving unit GIP, the low-potential voltage line VSSL, the first dam D1, and the second dam D2 and come into direct contact with an outer surface of the second touch insulating layer 184, but the embodiments of the present disclosure are not limited thereto.

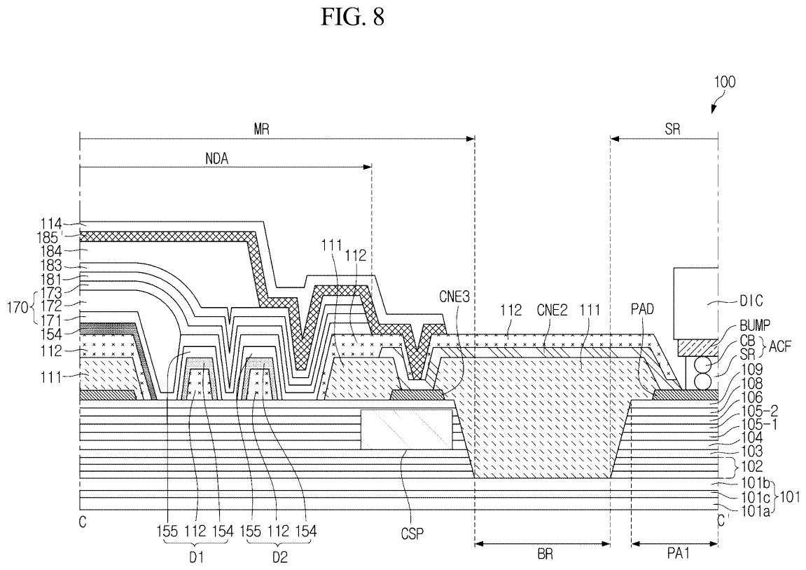

FIG. 8 is a cross-sectional view along line C-C′ in FIG. 1.

Referring to FIGS. 3, 7, and 8, the bending region BR can be disposed between the sub-region SR and the crack sensing pattern CSP. In the bending region BR, the panel inorganic layers 102, 103, 104, 105, 106, 107, and 109 can be removed to expose the upper surface of the substrate 101.

In the first pad area PA1, a pad electrode PAD disposed on the same layer as the first source electrode 121 (see FIG. 3) can be disposed, and a third connection electrode CNE3 disposed on the same layer as the first source electrode 121 (see FIG. 3) can be disposed on the crack sensing pattern CSP.

The first protective layer 111 can be disposed on the pad electrode PAD and the third connection electrode CNE3. The first protective layer 111 can be disposed in the bending region BR, and the first protective layer 111 can come into direct contact with the upper surface of the substrate 101 and in the bending region BR, the first protective layer 111 can come into direct contact with the side surfaces of the panel inorganic layers 102, 103, 104, 105, 106, 107, and 109.

A second connection electrode CNE2 can be disposed on the first protective layer 111, and the second connection electrode CNE2 can be disposed on the same layer as the connection electrode 145 (see FIG. 3). The second connection electrode CNE2 can electrically connect the pad electrode PAD to the third connection electrode CNE3. The second connection electrode CNE2 can be disposed on the bending region BR and can also be disposed on the first pad area PA1 and the crack sensing pattern CSP.

The data driving unit DIC can be disposed on the pad electrode PAD. The data driving unit DIC can include a bump BUMP, an anisotropic conductive film ACF can be disposed between the pad electrode PAD and the bump BUMP, and the anisotropic conductive film ACF can electrically connect the pad electrode PAD to the bump BUMP. The anisotropic conductive film ACF can include a resin SR and a plurality of conductive balls CB dispersed in the resin SR. The pad electrode PAD and the bump BUMP can be electrically connected through the conductive balls CB.

The second protective layer 112 can be disposed on the second connection electrode CNE2. The second protective layer 112 can expose the pad electrode PAD.

The first and second encapsulation layers 171 and 173 of the encapsulation part 170 can extend until before the bending region BR. For example, the first and second encapsulation layers 171 and 173 can extend until before the crack sensing pattern CSP, but the embodiments of the present disclosure are not limited thereto, and the first and second encapsulation layers 171 and 173 can also overlap the crack sensing pattern CSP. The first and second encapsulation layers 171 and 173 may not be disposed in the bending region BR.

The touch buffer layer 181 and the first touch insulation layer 183 can extend until before the bending region BR. For example, the touch buffer layer 181 and the first touch insulating layer 183 can extend until before the crack sensing pattern CSP, but the embodiments of the present disclosure are not limited thereto, and the touch buffer layer 181 and the first touch insulating layer 183 can also overlap the crack sensing pattern CSP. The touch buffer layer 181 and the first touch insulation layer 183 may not be disposed in the bending region BR.

The second touch insulating layer 184 can overlap the first dam D1 and the second dam D2. The second touch insulating layer 184 may not be disposed outside the second dam D2, but the embodiments of the present disclosure are not limited thereto.

A touch connection line 185′ can be electrically connected to the second connection electrode CNE2. The touch connection line 185′ can serve to provide signals applied from the pad electrode PAD and the second connection electrode CNE2 to the first sensor electrode 185a or the second sensor electrode 185b described above in FIG. 3. The touch connection line 185′ can be located on the same layer as the second touch conductive layer (the first sensor electrode 185a of FIG. 3), but the embodiments of the present disclosure are not limited thereto, and the touch connection line 185′ can be located on the same layer as the first touch conductive layer (the bridge electrode 182 of FIG. 3) or formed of two first and second touch conductive layers, but the embodiments of the present disclosure are not limited thereto.

The filter insulating layer 114 can be disposed on the touch connection line 185′, and the filter insulating layer 114 may not be disposed in the bending region BR.

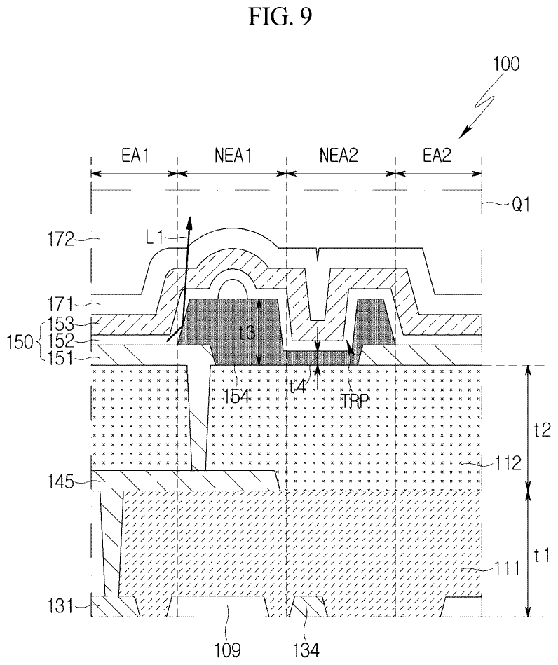

FIG. 9 is an enlarged cross-sectional view of area Q1 in FIG. 3.

Referring to FIGS. 3 and 9, the bank 154 according to one embodiment of the present disclosure can include a black-based material, and the first protective layer 111 or the second protective layer 112 can also include the black-based material. FIGS. 3 and 9 illustrate examples of the first protective layer 111 and the second protective layer 112 each including a black-based material. In some embodiments of the present disclosure, the bank 154, the first protective layer 111, or the second protective layer 112 may not include a black-based material, but can include a blue-based material or a mixed material of red-based, green-based, and blue-based materials to display black. For convenience of description, the following description will focus on the bank 154, the first protective layer 111, or the second protective layer 112, which includes a black-based material.

The bank 154 can include the trench TRP in the second non-light-emitting area NEA2. A thickness t4 of the bank 154 in which the trench TRP is formed can be smaller than a thickness t3 of the bank 154 in which the trench TRP is not formed.

As described above, the bank 154 can suppress surface reflection of external light. For example, the first bank 154 can absorb external light by including a black-based material. For example, the bank 154 can include a resin, a black-based material in the resin, an additive for dispersing the black-based material in the resin, etc. For example, the resin can include an organic material, such as a benzocyclobutene resin, a polyimide resin, an acrylic resin, a photosensitive polymer, etc., and the additive can be, for example, a dispersant, but the embodiments of the present disclosure are not limited thereto.

When forming the bank 154, the bank 154 can easily absorb external light when a ratio of the black-based material is high. The concept of the bank 154 absorbing external light is related to the optical density. The higher the optical density (hereinafter referred to as an “OD”), which is an index of a specific material absorbing light, the higher a light absorption rate. For example, the lower the OD, the higher the light transmittance. For example, the OD can be calculated using 1 μm as a reference thickness and proportional to a thickness. Hereinafter, the OD calculated using 1 μm as the reference thickness is referred to as a “reference OD,” and a thickness reflecting a thickness of an actual structure is referred to as an “actual OD.” For example, when the plurality of layers (e.g., 111, 112, and 154) have the same reference OD, the content of the black-based material can vary according to a thickness. A layer with a greater thickness can include more black-based material. For example, the content of the black-based material can vary according to the thicknesses of the first protective layer 111, the second protective layer 112, and the bank 154, and furthermore, a layer with a greater thickness among the first protective layer 111, the second protective layer 112, and the bank 154 can have a higher content of the black-based material.

The reference OD can be the same when the content of the black-based material is the same.

For example, the thickness t3 of the bank 154 in which the trench TRP is not formed can be about 1500 nm, and the thickness t4 of the bank 154 in which the trench TRP is formed can be about 500 nm. In this case, an actual OD of the bank 154 in which the trench TRP is not formed can be about 1.2, and an actual OD of the bank 154 in which the trench TRP is formed can be about 0.4. As described above, the lower the OD, the lower the light transmittance can be, and furthermore, the lower the actual OD, the lower the light transmittance can be. Accordingly, a light transmittance of the bank 154 in which the trench TRP is not formed can be higher than a light transmittance of the bank 154 in which the trench TRP is formed.

As described above, the bank 154 can suppress the surface reflection of external light, thereby suppressing external light from penetrating the semiconductor layers 123 and 133 of FIG. 3. For example, when external light penetrates channel areas of the semiconductor layers 123 and 133, even when the transistors 120 and 130 including the semiconductor layers 123 and 133 are turned off, a leakage current can be caused by the penetrated external light. Accordingly, noise can occur in the transistors 120 and 130. In particular, since the actual OD in the bank 154 in which the trench TRP is not formed is about 0.4, the leakage current issue can be a bigger problem.

Accordingly, to increase the actual OD of the bank 154, a method of increasing the thickness of the bank 154 can be considered, but this can run counter to the slimming of the display panel 100. As another method, an increase in the content of the black-based material in the bank 154 can be considered. To increase the content of the black-based material, the content of the additive for dispersing the black-based material in the resin also needs to be increased. However, when the content of the black-based material and the content of the additive are increased at the same time, the content of the resin for maintaining the shape of the bank 154 needs to be reduced, thereby causing structural defects or process defects in the display panel. In addition, since the additive affects peripheral components when vaporized, a process defect rate can increase.

Accordingly, it can be realistically difficult to increase the actual OD of the bank 154 compared to the currently applied OD.

To supplement the actual OD of the bank 154 (or the actual OD of the bank 154 in which the trench TRP is formed), the display panel 100 according to one embodiment of the present disclosure can be designed so that the protective layer includes a black-based material. Accordingly, even when the reference OD of the bank 154 is slightly reduced, the high total OD of the display panel 100 can be maintained.

For example, the protective layer can include the first protective layer 111 and the second protective layer 112, and the first protective layer 111 or the second protective layer can include a black-based material. Each of the thickness t1 of the first protective layer 111 and the thickness t2 of the second protective layer 112 can be greater than the thickness t3 of the bank 154. Accordingly, when a black-based material is applied to the first protective layer 111 or the second protective layer 112, as described above, the actual OD is proportional to a thickness, and thus a high actual OD can be formed. FIG. 9 illustrate an example in which the black-based material is added to each of the first protective layer 111 and the second protective layer 112.

For example, since the thicknesses t1 and t3 of the first and second protective layers 111 and 112 are greater than the thickness t3 of the bank 154, even when the reference OD of the bank 154 and the reference ODs of the first and second protective layers 111 and 112 are set to similar levels, the actual ODs of the first and second protective layers 111 and 112 can be set to be higher than the actual OD of the bank 154. The first and second protective layers 111 and 112 can overlap the bank 154 and overlap the trench TRP of the bank 154.

Hereinafter, a case in which only the second protective layer 112 includes a black-based material will be described with a numerical example.

For example, the reference OD of the bank 154 can be about 0.5, and the reference OD of the second protective layer 112 can be 0.5. The thickness t2 of the second protective layer 112 can be greater than the thickness t3 of the bank 154 and can be, for example, about 2000 nm. As described above, since the actual OD is proportional to a thickness, the actual OD of the second protective layer 112 can be 1.0. The total OD can be the sum of the actual ODs of the corresponding areas (overlapping areas in the thickness direction). For example, since the actual OD of the bank 154 in the area in which the trench TRP is not formed is about 0.75 and the actual OD of the second protective layer 112 is about 1.0, the total OD can be about 1.75. In addition, since the actual OD of the bank 154 in the area in which the trench TRP is not formed is about 0.75 and the actual OD of the second protective layer 112 is about 1.0, the total OD can be about 1.75. In addition, since the actual OD of the bank 154 in the area in which the trench TRP is formed is about 0.23 and the actual OD of the second protective layer 112 is about 1.0, the total OD can be about 1.23. Light transmittances of the bank 154 and the second protective layer 112 when the total OD is about 1.75 can be about 2%, and light transmittances of the bank 154 and the second protective layer 112 when the total OD is about 1.23 can be about 6%.

On the other hand, when the reference OD of the bank 154 is about 0.8 and the reference OD of the second protective layer 112 is zero (when no black-based material is added to the second protective layer 112), the actual OD of the bank 154 in the area in which the trench TRP is not formed is about 1.2, and the actual OD of the bank 154 in the area in which the trench TRP is formed is about 0.4. Accordingly, the total OD of the bank 154 in the area in which the trench TRP is not formed can be about 1.2, and the total OD of the bank 154 in the area in which the trench TRP is formed can be about 0.4. The light transmittance of the bank 154 when the total OD is about 1.2 can be about 6%, and the light transmittance of the bank 154 when the total OD is about 0.4 can be about 40%.

Compared to the above examples in which the black-based material is also added to the second protective layer 112, when the reference OD similar to that of the bank 154 was applied to the second protective layer 112, it could be confirmed that a higher level of the total OD could be derived due to the large thickness of the second protective layer 112 even when the high reference OD was not applied to the bank 154.

Accordingly, in the display panel 100 according to one embodiment of the present disclosure, the reference OD of the bank 154 can be reduced, thereby overcoming the above problem of the process defect rate.

In addition, using the actual OD of the protective layer along with the bank 154, the high total OD of the display panel 100 in the thickness direction can be formed. In particular, the low actual OD of the bank 154 in the trench TRP can be supplemented. Accordingly, it is possible to minimize a leakage current and noise that are caused by external light penetrating the channel area of the semiconductor layers 123 and 133.

Hereinafter, a display device according to other embodiments will be described. In the following embodiments of the present disclosure, the detailed description of the reference numerals or components described in FIGS. 1 to 9 will be omitted, or the overlapping descriptions thereof will be omitted.

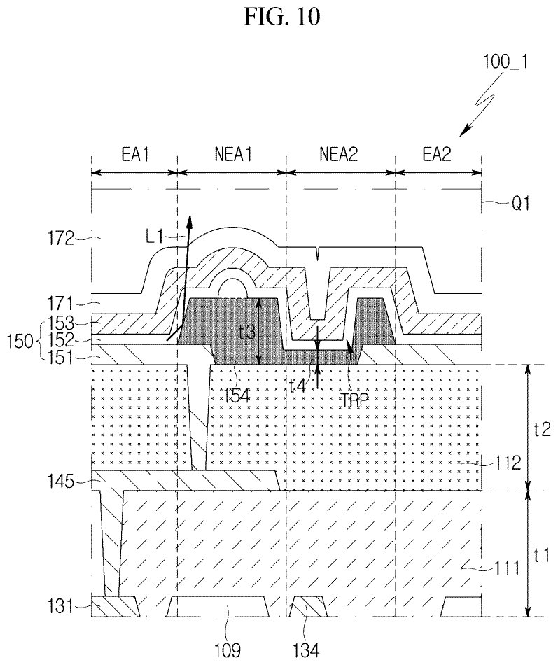

FIG. 10 is a cross-sectional view of a display device according to another embodiment of the present disclosure.

Referring to FIG. 10, a display panel 100_1 of the display device according to the present embodiment differs from the display panel 100 according to FIG. 9 in that the reference OD of the first protective layer 111 is lower than the reference OD of the second protective layer 112.

More specifically, the second protective layer 112 can come into direct contact with the bank 154. Accordingly, when the black-based material is not added to the second protective layer 112 (e.g. when the second protective layer 112 is a transparent protective layer), external light that has passed through the bank 154 can be highly likely reflected at the boundary between the bank 154 and the second protective layer 112. Accordingly, the black-based material is preferably added to the second protective layer 112. On the other hand, external light can hardly reach the first protective layer 111 due to the high total OD formed by the bank 154 and the second protective layer 112. Accordingly, the reference OD of the first protective layer 111 can be set to be lower than the reference OD of the second protective layer 112. In conclusion, according to the present embodiment, since the external light is almost absorbed by the second protective layer 112 and the bank 154 and the remaining external light is absorbed by the first protective layer 111, it is possible to improve an increase in cost and the process defect rate due to the additive of the first protective layer 111.

Since the remaining parts have been described above in FIG. 9, the detailed descriptions thereof will be omitted.

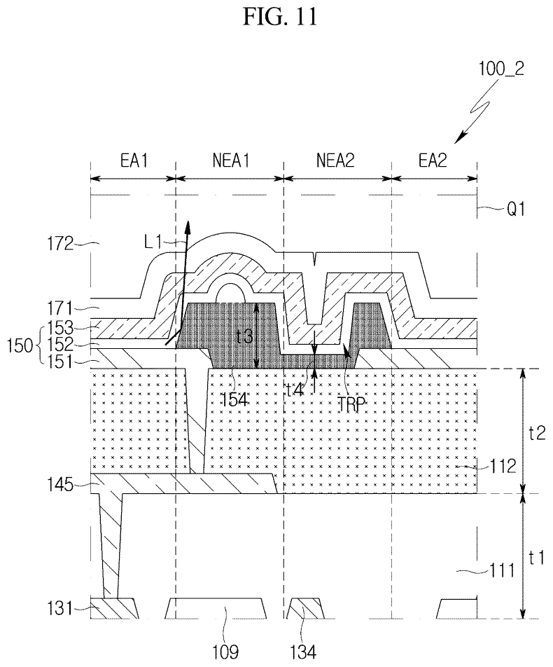

FIG. 11 is a cross-sectional view of a display device according to still another embodiment of the present disclosure.

Referring to FIG. 11, a display panel 100_2 of the display device according to the present embodiment differs from the display panel 100 100 according to FIG. 9 in that the first protective layer 111 can be a transparent protective layer.

More specifically, the second protective layer 112 can come into direct contact with the bank 154. Accordingly, when the black-based material is not added to the second protective layer 112 (e.g. when the second protective layer 112 is a transparent protective layer), external light that has passed through the bank 154 can be highly likely reflected at the boundary between the bank 154 and the second protective layer 112. Accordingly, the black-based material is preferably added to the second protective layer 112. On the other hand, external light can hardly reach the first protective layer 111 due to the high total OD formed by the bank 154 and the second protective layer 112. Accordingly, the first protective layer 111 can be formed as a transparent protective layer. In conclusion, according to the present embodiment, since the second protective layer 112 and the bank 154 serve to absorb external light and the first protective layer 111 is formed as a transparent protective layer like the conventional one, it is possible to improve an increase in cost and the process defect rate due to the additive of the first protective layer 111.

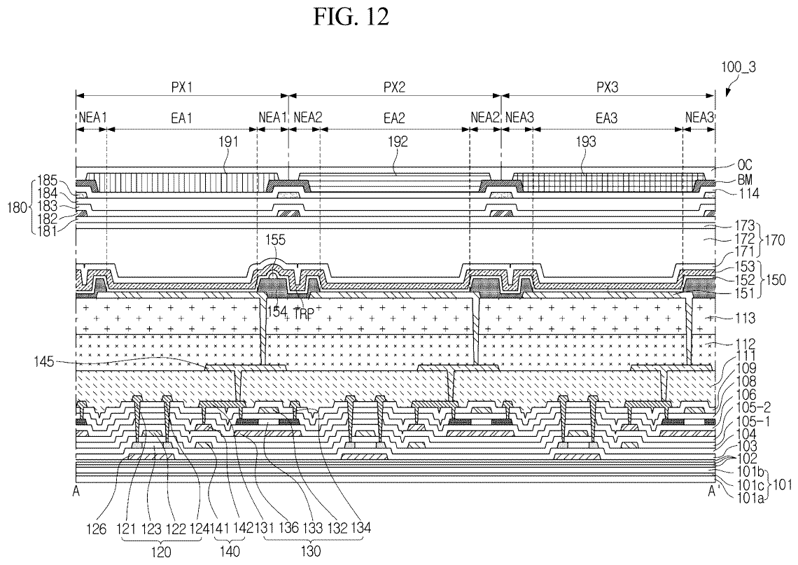

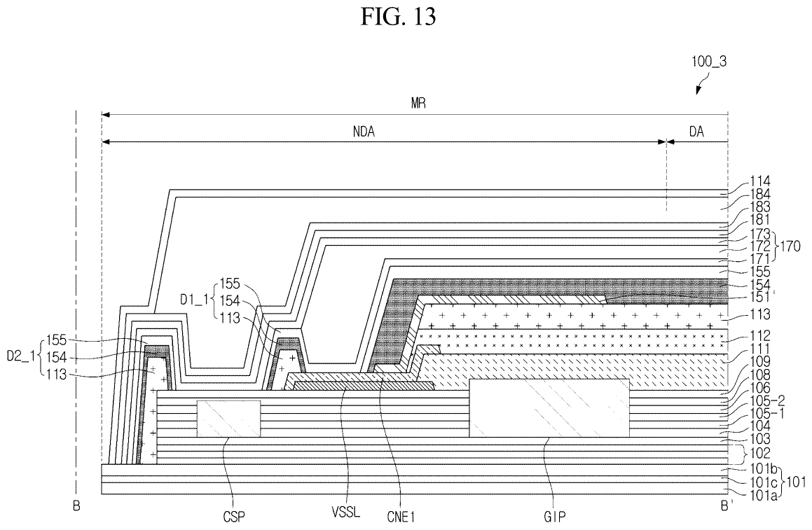

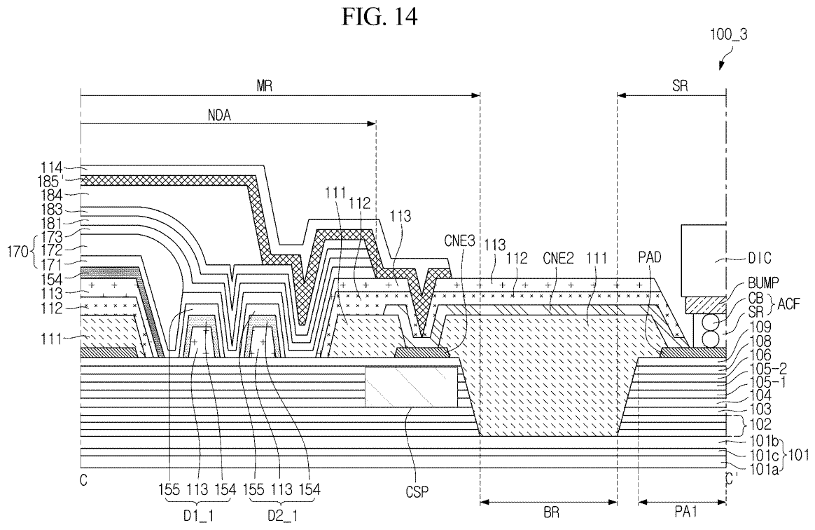

FIG. 12 is a cross-sectional view of a display device according to yet another embodiment of the present disclosure. FIG. 13 is a cross-sectional view of the display device according to yet another embodiment of the present disclosure. FIG. 14 is a cross-sectional view of the display device according to yet another embodiment of the present disclosure.

Referring to FIGS. 12 to 14, a display panel 100_3 of the display device according to the present embodiment differs from the display panel 100 according to FIGS. 3, 7, and 8 in that it can further include a third protective layer 113 on the second protective layer 112.

More specifically, the display panel 100_3 according to the present embodiment can further include the third protective layer 113 between the second protective layer 112 and the first electrode 151. A material of the third protective layer 113 can include at least one of materials exemplified as the material of the second protective layer 112, and the black-based material can be added to the third protective layer 113. A thickness of the third protective layer 113 can be greater than a thickness of the bank 154.

As illustrated in FIGS. 13 and 14, each of a first dam D1_1 and a second dam D2_1 can include the third protective layer 113 as a first layer and may not include the second protective layer 112, but the embodiments of the present disclosure are not limited thereto.

Since the remaining parts have been described above in FIGS. 3, 7, and 8, the detailed descriptions thereof will be omitted below.

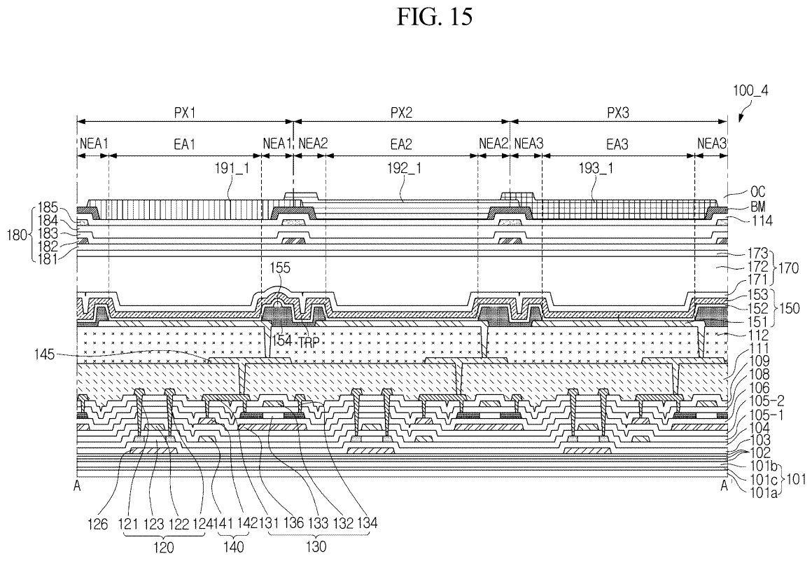

FIG. 15 is a cross-sectional view of a display device according to yet another embodiment of the present disclosure.

Referring to FIG. 15, color filters 191_1, 192_1, and 193_1 of a display panel 100_3 of the display device according to the present embodiment differ from the display panel 100 according to FIG. 4 in that they can overlap each other in the non-light-emitting areas NEA1, NEA2, and NEA3.

FIG. 15 illustrates that a second color filter 192_1 is located at the top, a first color filter 191_1 is located under the second color filter 192_1, and lastly a third color filter 193_1 is located at the bottom in each non-light-emitting area NEA1, NEA2, or NEA3, but the stacking order of each color filter 191_1, 192_1, or 193_1 in the non-light-emitting areas NEA1, NEA2, and NEA3 can vary according to a process order.

Since the remaining parts have been described above in FIG. 3, the detailed descriptions thereof will be omitted.

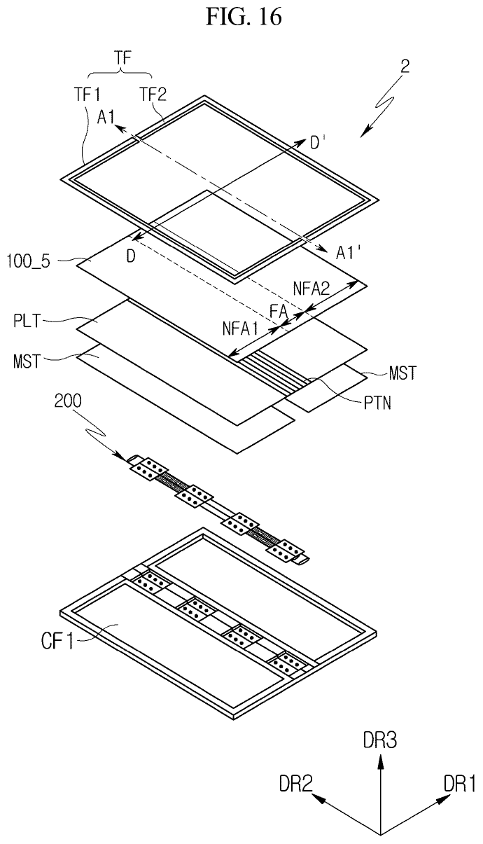

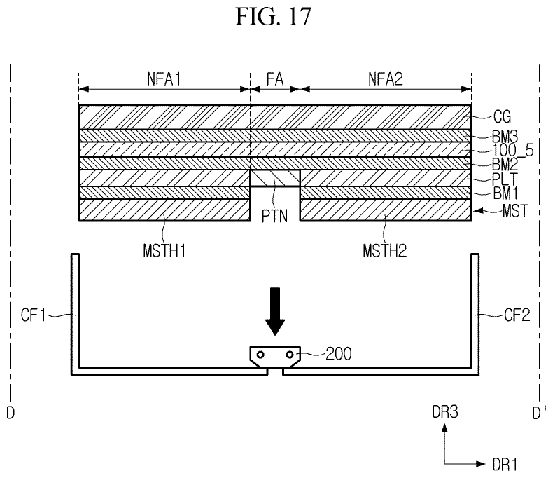

FIG. 16 is a perspective view of a display device according to yet another embodiment of the present disclosure. FIG. 17 is a cross-sectional view along line D-D′ in FIG. 16.

Referring to FIGS. 16 and 17, a display device 2 according to the present embodiment differs from the display device 1 according to FIG. 1 in that it is a foldable display device.

In the present disclosure, a folding axis A1 along which the display device 2 is folded can be the same as the second direction DR2.

A top frame TF is disposed at the top of the display device 2. With respect to the folding axis A1, the top frame TF includes a first top frame TF1 disposed at one side and a second top frame TF2 disposed at the other side. The top frame TF can be disposed to cover an edge of the display panel 100_5. The top frame TF can protect the display panel 100_5 from an external impact. The top frame TF can form a bezel of the display device 2.

A cover member CG can be disposed under the top frame TF. The cover member CG can be disposed above the display panel 100_5. The cover member CG can be formed of a glass material including glass, quartz, etc., but the embodiments of the present disclosure are not limited thereto, and the cover member 300 can be formed of a plastic material.

The cover member CG can be disposed above the display panel 100_5 to protect members disposed under the cover member CG from the outside.

A panel assembly is disposed under the cover member CG. The panel assembly includes the display panel 100_5 and a plate PLT. The display panel 100_5 can be substantially the same as one of the display panels 100_1, 100_2, 100_3, and 100_4.

The plate PLT can be disposed under the display panel 100_5 and can include various plates for supporting the display panel 100_5. For example, one or more plates can include a back plate for supporting the display panel 100_5, a top plate disposed under the back plate and formed of a stainless steel (SUS) material, a bottom plate disposed under the top plate, having a pattern formed on a folding portion, and formed of a SUS material, a heat-dissipation sheet that performs a heat-dissipation function, a middle plate for covering a non-planarized flat surface caused by various components of a hinge assembly, etc.

A slit pattern PTN can be formed in the plate PLT. The slit pattern PTN can be formed at a location corresponding to a folding area FA of the display panel 100_5. The slit pattern PTN can be a slit-shaped etched portion formed in the plate PLT. For example, the plate PLT can be formed of a metal, such as a SUS material, but the strong nature of the metal can cause problems in folding or unfolding the plate PLT. The slit pattern PTN can supplement the flexibility of the plate PLT.

A middle plate MST is disposed under the panel assembly. The middle plate MST supports components disposed upward. In addition, a hinge assembly 200 and a cover frame CF are disposed downward from the middle plate MST, and their upper surfaces can be uneven. The middle plate MST can flatten a non-planarized lower surface. The middle plate MST can be formed of a material, such as plastic, polyimide, or metal, to increase the rigidity of the display device 2. For example, the middle plate MST can include aluminum or SUS, but is not limited thereto.

The middle plate MST can include a first middle plate portion MSTH1 disposed in a first unfolding area NFA1, and a second middle plate portion MSTH2 disposed in a second unfolding area NFA2.

The hinge assembly 200 is disposed under the panel assembly. The hinge assembly 200 is disposed under the folding area FA. The hinge assembly 200 can have a shape extending along the folding axis A1. The hinge assembly 200 can perform a folding motion in which one side and the other side rotate about the folding axis A1.

The cover frame CF is disposed under the hinge assembly 200. An accommodation groove in which a part of the hinge assembly 200 can be seated can be formed in an upper surface of the cover frame CF. With respect to the folding axis A1, the cover frame CF includes a first cover frame CF1 disposed at one side and a second cover frame CF2 disposed at the other side. The cover frame CF can be a housing for defining the side and rear surfaces of the display device 2. The cover frame CF can protect the display device 2 from an external impact. The cover frame CF can be coupled to the hinge assembly 200. Folding and unfolding of the display device 2 can be implemented according to the rotation of the cover frames CF1 and CF2.

Coupling members BM1, BM2, and BM3 for coupling the adjacent members MST, PLT, PNL, and CG can be further disposed between the adjacent members. In each of the unfolding areas NFA1 and NFA2, a first coupling member BM1 can couple the middle plate portions MSTH1 and MSTH2 to the plate PLT disposed above the middle plate portions MSTH1 and MSTH2, a second coupling member BM2 can couple the plates PLT and PTN to the display panel 100_5 disposed above the plates PLT and PTN, and a third coupling member BM3 can couple the display panel 100_5 to the cover member CG.

The plate PLT and the middle plate MST that are coupled can be seated on the cover frames CF1 and CF2. The display device 2 can perform folding and unfolding operations by the hinge assembly 200 disposed on the cover frames CF1 and CF2.

Since the display panel 100_5 has been described above, the detailed descriptions thereof will be omitted below.

A display device according to various embodiments of the present disclosure can be described as follows.

According to embodiments of the present disclosure, there is provided a display device including a substrate including a display area including a plurality of sub-pixels, and a non-display area around the display area, a first transistor on the substrate, a second transistor on the first transistor, a first protective layer on the second transistor, a connection electrode connected to the second transistor on the first protective layer, a second protective layer on the connection electrode, a first electrode disposed in each of the sub-pixels on the second protective layer and connected to the connection electrode, and a bank disposed on the first electrode, located at a boundary between adjacent sub-pixels, overlapping a periphery of an upper surface of the first electrode, and including a trench portion recessed in a thickness direction, in which the bank includes a black-based material, and the first protective layer or the second protective layer includes the black-based material.

In the display device according to the embodiments of the present disclosure, the sub-pixel can include a light-emitting area corresponding to the first electrode exposed by the bank, and a non-light-emitting area around the light-emitting area, and the trench can be located in the non-light-emitting area.

In the display device according to the embodiments of the present disclosure, a thickness of the bank in the trench can be smaller than a thickness of the bank in which the trench is not formed.

In the display device according to the embodiments of the present disclosure, the first protective layer and the second protective layer can overlap the trench.

In the display device according to the embodiments of the present disclosure, a thickness of the first protective layer or the second protective layer can be greater than a thickness of the bank.

In the display device according to the embodiments of the present disclosure, a semiconductor layer of the first transistor can include a polysilicon, and a semiconductor layer of the second transistor can include an oxide.

The display device according to various embodiments of the present disclosure can further include a third protective layer between the second protective layer and the first electrode, in which the third protective layer can include the black-based material.

In the display device according to the embodiments of the present disclosure, a thickness of the third protective layer can be greater than a thickness of the bank.

In the display device according to the embodiments of the present disclosure, the plurality of sub-pixels can include a first sub-pixel, a second sub-pixel, and a third sub-pixel, and the organic layer can be disposed across the first sub-pixel, the second sub-pixel, and the third sub-pixel.

In the display device according to the embodiments of the present disclosure, the organic layer can include a first light-emitting layer on the first sub-pixel, a second light-emitting layer on the second sub-pixel, and a third light-emitting layer on the third sub-pixel.

In the display device according to the embodiments of the present disclosure, in the each sub-pixel, each of the first light-emitting layer, the second light-emitting layer, and the third light-emitting layer can be stacked in two or more layers.

The display device according to various embodiments of the present disclosure can further include an organic layer on the first electrode, a second electrode on the organic layer, and a black matrix located at a boundary between adjacent sub-pixels on the second electrode, in which a width of the black matrix can be smaller than a width of the bank.

In the display device according to the embodiments of the present disclosure, an end portion of the black matrix can be closer to the boundary between the sub-pixels than an end portion of the bank.

The display device according to the embodiments of the present disclosure can further include a touch part on the second electrode, in which the touch part can include a bridge electrode, and a sensor electrode on the bridge electrode, and the black matrix can overlap the bridge electrode and the sensor electrode.

According to embodiments of the present disclosure, there is provided a display device including a substrate including a display area including a plurality of sub-pixels and a non-display area around the display area, a transistor on the substrate, a first protective layer on the transistor, a connection electrode connected to the transistor on the first protective layer, a second protective layer on the connection electrode, a first electrode disposed in each of the sub-pixels on the second protective layer and connected to the connection electrode, and a bank disposed on the first electrode, located at a boundary between adjacent sub-pixels, overlapping a periphery of an upper surface of the first electrode, and including a trench recessed in a thickness direction, in which the first protective layer and the second protective layer each have a greater thickness than the bank, the bank includes a black-based material, and the first protective layer or the second protective layer includes the black-based material.

In the display device according to the embodiments of the present disclosure, the sub-pixel can include a light-emitting area corresponding to the first electrode exposed by the first bank, and a non-light-emitting area around the light-emitting area, and the trench can be located in the non-light-emitting area.

In the display device according to the embodiments of the present disclosure, a thickness of the bank in the trench can be smaller than a thickness of the bank in which the trench is not formed.

In the display device according to the embodiments of the present disclosure, the first protective layer and the second protective layer can overlap the trench.

The display device according to various embodiments of the present disclosure can further include a third protective layer between the second protective layer and the first electrode, in which the third protective layer can include the black-based material.

In the display device according to the embodiments of the present disclosure, a thickness of the third protective layer can be greater than a thickness of the bank.

In the display device according to the embodiments of the present disclosure, the bank can include the black-based material, thereby improving the external light introduced into the semiconductor layer.

In the display device according to the embodiments of the present disclosure, by slightly reducing the optical density of the bank and including the protective layer including the black-based material, it is possible to maintain the proper optical density of the display panel (the total optical density is proportional to a thickness), thereby improving the external light introduced into the semiconductor layer.

In the display device according to the embodiments of the present disclosure, to improve the lateral leakage current of the organic layer, the trench can be formed in the bank, and the trench can overlap the protective layer including the black-based material to compensate for the low optical density in the trench.

In the display device according to the embodiments of the present disclosure, by slightly reducing the optical density of the bank, it is possible to reduce the amount of an additive for forming the bank, thereby improving recycling.

However, effects obtainable from the present disclosure are not limited to the above-described effects, and other effects that are not mentioned will be able to be clearly understood by those skilled in the art to which the present disclosure pertains based on the following description.

Although the embodiments of the present disclosure have been described above with reference to the accompanying drawings, those skilled in the art to which the present disclosure pertains will be able to understand that the above-described technical configuration of the present disclosure can be carried out in other specific forms without changing the technical spirit or essential features thereof. Accordingly, it should be understood that the above-described embodiments are illustrative and not restrictive in all respects. In addition, the scope of the present disclosure is described by the claims to be described below rather than the detailed description. In addition, the meaning and scope of the claims and all changed or modified forms derived from the equivalent concept should be construed as being included in the scope of the present disclosure.

### Description of Reference Numerals

1: display device
100, 100_1, 100_2, 100_3, 100_4, 100_5: display panel
D1, D2: dam

What is claimed is:

1. A display device comprising:
a substrate including a display area having sub-pixels, and a non-display area around the display area;
a first transistor on the substrate;
a second transistor on the first transistor;
a first protective layer on the second transistor;
a connection electrode connected to the second transistor on the first protective layer;
a second protective layer on the connection electrode;
a first electrode disposed in each of the sub-pixels on the second protective layer and connected to the connection electrode; and
a bank disposed on the first electrode, located at a boundary between adjacent sub-pixels, overlapping a periphery of an upper surface of the first electrode, and including a trench recessed in a thickness direction,
wherein the bank includes a black-based material, and
wherein the first protective layer or the second protective layer includes the black-based material.

2. The display device of claim 1, wherein one of the sub-pixels includes a light-emitting area corresponding to the first electrode exposed by the first bank, and a non-light-emitting area around the light-emitting area, and
wherein the trench is located in the non-light-emitting area.

3. The display device of claim 2, wherein a thickness of the bank in the trench is smaller than a thickness of the bank in which the trench is not formed.

4. The display device of claim 3, wherein the first protective layer and the second protective layer overlap the trench.

5. The display device of claim 1, wherein a thickness of the first protective layer or the second protective layer is greater than a thickness of the bank.

6. The display device of claim 1, wherein a semiconductor layer of the first transistor includes a polysilicon, and a semiconductor layer of the second transistor includes an oxide.

7. The display device of claim 1, further comprising a third protective layer between the second protective layer and the first electrode, wherein the third protective layer includes the black-based material.

8. The display device of claim 7, wherein a thickness of the third protective layer is greater than a thickness of the bank.

9. The display device of claim 1, wherein the sub-pixels include a first sub-pixel, a second sub-pixel, and a third sub-pixel, and the organic layer is disposed across the first, second and third sub-pixels, and
wherein the organic layer includes a first light-emitting layer on the first sub-pixel, a second light-emitting layer on the second sub-pixel, and a third light-emitting layer on the third sub-pixel.

10. The display device of claim 9, wherein, in each of the sub-pixels, each of the first light-emitting layer, the second light-emitting layer, and the third light-emitting layer is stacked in two or more layers.

11. The display device of claim 1, further comprising:
an organic layer on the first electrode;
a second electrode on the organic layer; and
a black matrix located at a boundary between adjacent sub-pixels on the second electrode,
wherein a width of the black matrix is smaller than a width of the bank, and
wherein an end portion of the black matrix is closer to the boundary between the adjacent sub-pixels than an end portion of the bank.

12. The display device of claim 11, further comprising a touch part on the second electrode, wherein the touch part includes a bridge electrode, and a sensor electrode on the bridge electrode, and
wherein the black matrix overlaps the bridge electrode and the sensor electrode.

13. The display device of claim 1, wherein a content of the black-based material varies according to thicknesses of the first protective layer, the second protective layer, and the bank.

14. The display device of claim 13, wherein a layer with a greater thickness among the first protective layer, the second protective layer, and the bank has a higher content of the black-based material.

15. A display device comprising:
a substrate including a display area including sub-pixels, and a non-display area around the display area;
a transistor on the substrate;
a first protective layer on the transistor;
a connection electrode connected to the transistor on the first protective layer;
a second protective layer on the connection electrode;
a first electrode disposed in each of the sub-pixels on the second protective layer and connected to the connection electrode; and
a bank disposed on the first electrode, located at a boundary between adjacent sub-pixels, overlapping a periphery of an upper surface of the first electrode, and including a trench recessed in a thickness direction,
wherein each of the first protective layer and the second protective layer has a greater thickness than the bank,
wherein the bank includes a black-based material, and
wherein the first protective layer or the second protective layer includes the black-based material.

16. The display device of claim 15, wherein one of the sub-pixels includes a light-emitting area corresponding to the first electrode exposed by the first bank, and a non-light-emitting area around the light-emitting area, and
wherein the trench is located in the non-light-emitting area.

17. The display device of claim 16, wherein a thickness of the bank in the trench is smaller than a thickness of the bank in which the trench is not formed.

18. The display device of claim 17, wherein the first protective layer and the second protective layer overlap the trench.

19. The display device of claim 15, further comprising a third protective layer between the second protective layer and the first electrode,
wherein the third protective layer includes the black-based material.

20. The display device of claim 19, wherein a thickness of the third protective layer is greater than a thickness of the bank.
